(19) United States
(12) Patent Application Publication
(10) Pub. No.: US 2024/0290759 A1
(43) Pub. Date: Aug. 29, 2024

(54) SEMICONDUCTOR DEVICE

(71) Applicant: POWER MASTER SEMICONDUCTOR CO., LTD., Cheongju-si (KR)

(72) Inventors: Taekkeun LEE, Seoul (KR); In-Suk KIM, Bucheon-si (KR); Ki-Myung YOON, Bucheon-si (KR); Jooyaung EOM, Gimpo-si (KR); Soonho KWON, Bucheon-si (KR)

(21) Appl. No.: 18/582,905

(22) Filed: Feb. 21, 2024

(30) Foreign Application Priority Data
Feb. 22, 2023 (KR) 10-2023-0023772
Feb. 15, 2024 (KR) 10-2024-0022093

(51) Int. Cl. H01L 25/07; H01L 23/00; H01L 23/373

(52) U.S. Cl. CPC H01L 25/072; H01L 23/3735; H01L 24/40; H01L 24/48; H01L 2224/40139; H01L 2224/48139

(57) ABSTRACT

Provided is a semiconductor device. A semiconductor device is implemented as a semiconductor module package for driving an inverter, the semiconductor device may include: a first upper metal layer in which a plurality of first semiconductor chips implementing a switching pattern of a low voltage phase are disposed along a first row in a first direction; a first connection connecting the plurality of first semiconductor chips in series and extending to a second upper metal layer; and a first lead frame providing power to the semiconductor device from an external source through the second upper metal layer, wherein, in the second upper metal layer, a first vertically extending leg portion and a second vertically extending leg portion of the first lead frame forming a fork shape are disposed, and the first connection is disposed between the first vertically extending leg portion and the second vertically extending leg portion.

### CROSS-REFERENCE TO RELATED APPLICATION

This application claims priority to and the benefit of Korean Patent Application No. 10-2023-0023772 filed in the Korean Intellectual Property Office on Feb. 22, 2023, and Korean Patent Application No. 10-2024-0022093 filed in the Korean Intellectual Property Office on Feb. 15, 2024, the entire contents of which are incorporated herein by reference.

### BACKGROUND OF THE INVENTION

### (a) Field of the Invention

The present disclosure relates to a semiconductor device, and more specifically, to a semiconductor module package for driving an inverter.

### (b) Description of the Related Art

Power semiconductor devices are used to control and change electrical energy and can mainly operate under high voltage and high current conditions. Power semiconductor devices can be used in motor drive and battery management systems in electric and hybrid vehicles, can be used to precisely control the speed and torque of motors in factory automation and robotics, and can be widely used for power conversion and power supply in a variety of other high-power applications. Power semiconductor devices can operate under high voltage and high current conditions, so high efficiency and stability are required. For example, insulated gate bipolar transistors (IGBTs) are power electronics devices which have high-input impedance characteristics like metal oxide semiconductor field effect transistors (MOSFETs) and also have low conduction loss characteristics like bipolar junction transistors (BJTs), and are suitable for applications that require high switching speed while maintaining high voltage. As another example, silicon carbide (SiC) is a high-performance semiconductor material having higher electrical conductivity, higher thermal conductivity, the ability to operate devices at higher temperatures, higher voltage and current densities, higher switching speeds, as compared to silicon, and SiC semiconductors may be suitable for high-power, high-temperature, or high-frequency applications.

The semiconductor module for driving an inverter can convert direct current power to alternating current power through switching operations of power semiconductor devices. Power semiconductor devices can switch on/off states according to a set sequence and timing. Inductance is a property that resists changes in current in an electric circuit, and in order to increase performance and efficiency, it is necessary to minimize the inductance of the semiconductor module for driving the inverter.

### SUMMARY OF THE INVENTION

The present disclosure attempts to provide a semiconductor device including a semiconductor module package for driving an inverter designed to reduce inductance while minimizing size.

A semiconductor device according to an embodiment may be implemented as a semiconductor module package for driving an inverter, the semiconductor device may include: a first upper metal layer in which a plurality of first semiconductor chips implementing a switching pattern of a low voltage phase are disposed along a first row in a first direction; a first connection connecting the plurality of first semiconductor chips in series and extending to a second upper metal layer; and a first lead frame providing power to the semiconductor device from an external source through the second upper metal layer, wherein, in the second upper metal layer, a first vertically extending leg portion and a second vertically extending leg portion of the first lead frame forming a fork shape are disposed, and the first connection is disposed between the first vertically extending leg portion and the second vertically extending leg portion.

In some embodiments, a plurality of second semiconductor chips may be further disposed on the first upper metal layer along a second row parallel to the first row, and the semiconductor device may further include a second connection connecting the plurality of the second semiconductor chips in series and extending to a third upper metal layer, and wherein, in the third upper metal layer, a third vertically extending leg portion and a fourth vertically extending leg portion of the first lead frame forming the fork shape together with the first vertically extending leg portion and the second vertically extending leg portion may be disposed, and the second connection may be disposed between the third vertically extending leg and the fourth vertically extending leg portion.

In some embodiments, the first lead frame may include a horizontally extending portion along a second direction perpendicular to the first direction, and the first vertically extending leg portion, the second vertically extending leg portion, the third vertically extending leg portion, and the fourth vertically extending leg portion may be formed to extend in the same direction from the horizontally extending portion.

In some embodiments, the second upper metal layer and the third upper metal layer may be formed to be spaced apart from each other.

In some embodiments, a plurality of third semiconductor chips may be further disposed on the first upper metal layer along a third row parallel to the first row, and the semiconductor device may further include: a third connection connecting the plurality of third semiconductor chips in series and in parallel to each other; and a second lead frame disposed below the third connection on one side of the first lead frame and providing power to the semiconductor device.

In some embodiments, a plurality of fourth semiconductor chips may be further disposed on the first upper metal layer along a fourth row parallel to the first row, and the semiconductor device may further include: a fourth connection connecting the plurality of fourth semiconductor chips in series and in parallel to each other; and a third lead frame disposed below the fourth connection on the other side of the first lead frame and providing power to the semiconductor device.

In some embodiments, the first upper metal layer, the second upper metal layer, and the third upper metal layer may be included in an upper substrate, a ceramic layer may be formed under the upper substrate, and a lower metal layer may be formed under the ceramic layer.

In some embodiments, the first connection, the second connection, the third connection, and the fourth connection may include a clip or a wire.

### BRIEF DESCRIPTION OF THE DRAWINGS

FIG. 1 to FIG. 2 are drawings for explaining a semiconductor device according to an embodiment.

FIG. 3 is a partial view emphasizing the connection area between the connection and the lead frame in FIG. 1 to FIG. 2.

FIG. 4 is a cross-sectional view showing a cross-section along line AA′ in FIG. 1.

### DETAILED DESCRIPTION OF THE EMBODIMENTS

Hereinafter, embodiments of the present invention will be described in detail with reference to the accompanying drawings such that those skilled in the art can easily implement them. However, the present invention can be implemented in various different forms and is not limited to the following embodiments. The drawings are to be regarded as illustrative in nature and not restrictive. Like reference numerals designate like elements throughout the specification.

Throughout the specification and the claims, unless explicitly described to the contrary, the word “comprise”, and variations such as “comprises” or “comprising”, will be understood to imply the inclusion of stated elements but not the exclusion of any other elements. Meanwhile, throughout the specification and the claims, the terms “up”, “down”, “left” and “right” are relatively defined based on the accompanying drawings only for clearly and easily explaining embodiments, and it is clear that they are not intended to limit any component to an absolute specific direction in the present invention.

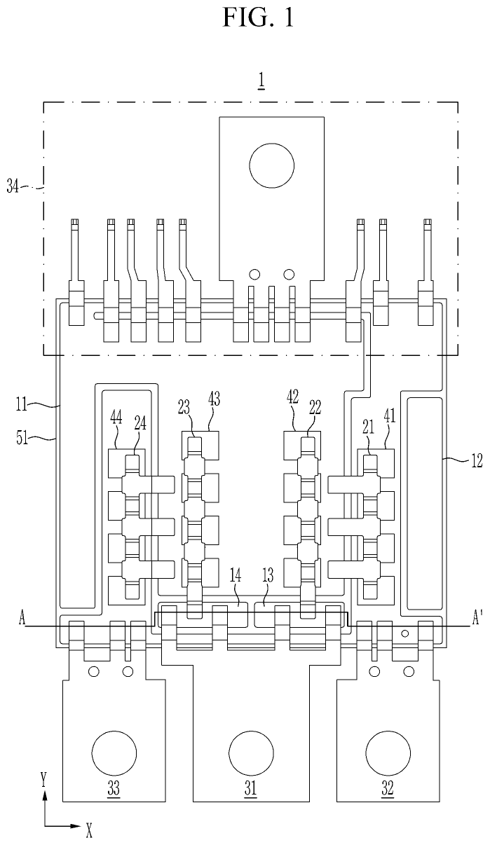

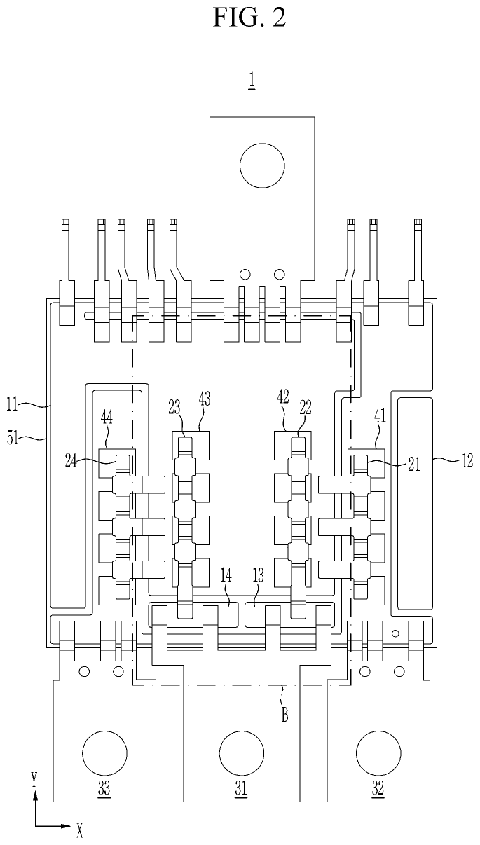

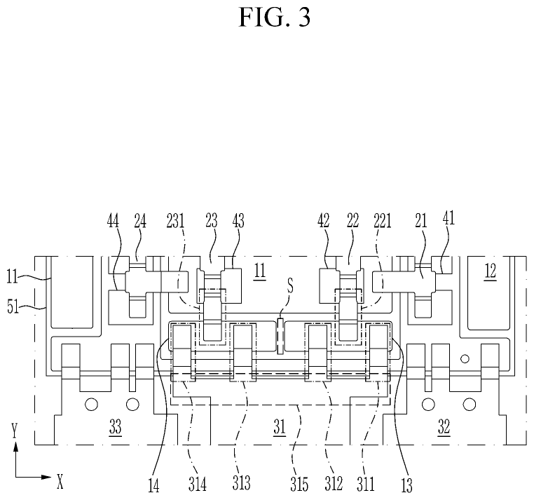

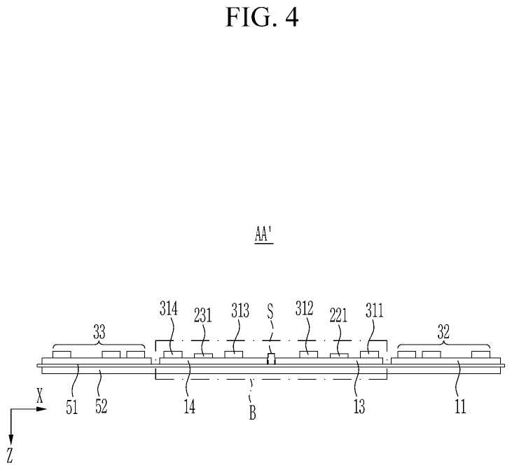

FIG. 1 to FIG. 2 are drawings for explaining a semiconductor device according to an embodiment. FIG. 3 is a partial view emphasizing the connection area between the connection and the lead frame in FIG. 1 to FIG. 2, and FIG. 4 is a cross-sectional view showing a cross-section along line AA′ in FIG. 1.

Referring to FIG. 1 to FIG. 4 together, a semiconductor device 1 according to an embodiment may include a direct bonding copper (DBC) substrate 10, external power terminals 31, 32, and 33, and external signal terminals 34. The DBC substrate 10 may include upper metal layers 11, 12, 13, and 14, a ceramic layer 51, and a lower metal layer 52. In this case, the ceramic layer 51 may be formed under the upper metal layers 11, 12, 13, and 14, and the lower metal layer 52 may be formed under the ceramic layer 51. In some embodiments, the upper metal layers 11, 12, 13, and 14, and the lower metal layer 52 may be made of Cu, and the ceramic layer 51 may be made of Aluminum Oxide (Al₂O₃), Aluminum Nitride (AlN), Beryllium Oxide (BeO), Silicon Carbide (SiC), or Silicon Nitride (Si₃N₄).

The semiconductor device 1 may be implemented as a semiconductor module package for driving an inverter. To this end, the semiconductor device 1 may include semiconductor chips on the upper metal layer 11.

Semiconductor chips implementing a switching pattern of a low voltage phase or a left phase may be disposed on the upper metal layer 11. Here, a low voltage phase or a left phase may represent a switching state in which a relatively lower voltage is applied to a specific phase of the inverter, for example, it may indicate that a lower switch is in ON state at a specific point in time for one phase. Specifically, in the upper metal layer 11, a plurality of semiconductor chips 42 may be disposed along the first direction Y to form a first row, and a plurality of semiconductor chips 43 are disposed along the first direction Y to form a second row to be parallel to the first row. In this specification, a semiconductor chip may include various types of power devices, including insulated gate bipolar transistors (IGBT) and silicon carbide (SiC) devices.

Meanwhile, semiconductor chips implementing a switching pattern of a high voltage phase or a right phase may be disposed on the upper metal layer 11. Here, a high voltage phase or a right phase may represent a switching state in which a relatively higher voltage is applied to a specific phase of the inverter, for example, it may indicate that a upper switch is in ON state at a specific point in time for one phase. Specifically, in the upper metal layer 11, a plurality of semiconductor chips 41 may be disposed along the first direction Y to form a third row to be parallel to the first row, and a plurality of semiconductor chips 44 are disposed along the first direction Y to form a fourth row to be parallel to the first row.

In this specification, “connection” refers to an element that electrically connects one element to another element and may refer to any type of component made using an electrically conductive material, for example, a clip or a wire. Therefore, it is clear that the scope of the present invention is not limited to the case where the connection is a clip, but for clarity and convenience of explanation, the case where the connection is a clip will be mainly used as an example.

On the upper metal layer 11, a plurality of semiconductor chips 42 disposed along the first row may be connected to each other in series by a connection 22, and a plurality of semiconductor chips 43 disposed along the second row may be connected to each other in series by a connection 23. The connection 22 may extend to the upper metal layer 13, and for this purpose, the connection 22 may include a vertically extending leg portion 221. Meanwhile, the connection 23 may extend to the upper metal layer 14, and for this purpose, the connection 23 may include a vertically extending leg portion 231.

Here, the upper metal layer 13 and the upper metal layer 14 may be formed to be spaced apart from each other with a space S. That is, as indicated by the dotted square B in FIG. 2, both the upper metal layer 13 and the upper metal layer 14 belong to the same voltage phase (corresponding to the low voltage phase) but are divided from each other.

Meanwhile, the plurality of semiconductor chips 41 disposed along the third row in the upper metal layer 11 may be connected to each other in series by the connection 21, and the plurality of semiconductor chips 44 disposed along the fourth row in the upper metal layer 11 may be connected to each other in series by the connection 24. In addition, the connection 21 may connect the plurality of semiconductor chips 41 in series and simultaneously connect the plurality of semiconductor chips 41 to the plurality of semiconductor chips 42 in parallel, and for this purpose, the connection 21 may include a leg portion formed to extend along the second direction X. Likewise, the connection 24 may connect the plurality of semiconductor chips 44 in series and simultaneously connect the plurality of semiconductor chips 44 to the plurality of semiconductor chips 43 in parallel, and for this purpose, the connection 24 may include a leg portion formed to extend along the second direction X.

According to the present embodiment, the connections 22 and 23 connect a plurality of semiconductor chips 42 and 43 disposed along the first row and the second row respectively in the upper metal layer 11 in series, the connections 21 and 24 connect a plurality of semiconductor chips 41 and 43 disposed along the third row and the fourth row respectively in the upper metal layer 11 in series and simultaneously connect the plurality of semiconductor chips 41 and 44 to the plurality of semiconductor chips 42 and 43 in parallel, so that circuit paths can be shortened and more direct, resulting in lower inductance.

The external power terminals 31, 32, and 33 may provide power to the semiconductor device 1 from an external source and may include a first lead frame 31, a second lead frame 32, and a third lead frame 33. The first lead frame 31 may provide power to the semiconductor device from the external source through the upper metal layers 13 and 14.

The first lead frame 31 may be formed in a fork shape. Specifically, as shown in detail in FIG. 3, the first lead frame 31 may include a plurality of vertically extending leg portions 311, 312, 313, and 314 formed to extend along the first direction Y, and a horizontally extending portion 315 formed to extend along the second direction X. The plurality of vertically extending leg portions 311, 312, 313, and 314 may be formed to extend in the same direction (upward direction based on the drawing) from the horizontally extending portion 315. As the width of the area connected to the outside (the area where a circular hole is formed in the lower part of the horizontally extending portion 315 in the drawing) is formed to be narrower than the horizontally extending portion 315, and the plurality of vertically extending leg portions 311, 312, 313, and 314 are formed at predetermined intervals in the horizontal length of the horizontally extending portion 315, the first lead frame 31 may have a table fork shape.

The vertically extending leg portions 311 and 312 of the first lead frame 31 forming a fork shape may be disposed in the upper metal layer 13, which is spaced apart from the upper metal layer 14 by a space S. And the connection 22 may be disposed between the vertically extending leg portion 311 and the vertically extending leg portion 312. Meanwhile, the vertically extending leg portions 313 and 314 of the first lead frame 31 forming the fork shape may be disposed in the upper metal layer 14, which is spaced apart from the upper metal layer 13 by a space S. And the connection 23 may be disposed between the vertically extending leg portion 313 and the vertically extending leg portion 314.

The upper metal layer 13 and the upper metal layer 14 both belong to the same voltage phase (corresponding to the low voltage phase), but are divided from each other, and the same voltage phases may be electrically connected to each other through the first lead frame 31.

The second lead frame 32 is disposed below the connection 21 on one side of the first lead frame 31 to provide power to the semiconductor device, and the third lead frame 33 is disposed below the connection 24 on the other side of the first lead frame 31 to provide power to the semiconductor device.

According to the embodiments described so far, clips designed to support both serial and parallel connection of semiconductor chips are used, the inductance can be lowered without increasing the size of the package by changing the arrangement of the semiconductor chip or increasing the number of connection terminals. In particular, by efficiently designing the spatial arrangement of the fork-shaped first lead frame and the connection connected to the semiconductor chip, and the arrangement of circuit elements including the second lead frame and third lead frame, the length of electrical flow can be minimized and inductance can be effectively lowered without affecting package size. In addition, by dividing the two upper metal layers that belong to the same voltage phase and adopting a structure that electrically connects the same voltage phase to each other through the first lead frame, the electrical flow may be implemented as a serial connection so that electrical loss due to parallel connection can be prevented.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device implemented as a semiconductor module package for driving an inverter, the semiconductor device comprising:
a first upper metal layer in which a plurality of first semiconductor chips implementing a switching pattern of a low voltage phase are disposed along a first row in a first direction;
a first connection connecting the plurality of first semiconductor chips in series and extending to a second upper metal layer; and
a first lead frame providing power to the semiconductor device from an external source through the second upper metal layer,
wherein, in the second upper metal layer, a first vertically extending leg portion and a second vertically extending leg portion of the first lead frame forming a fork shape are disposed, and the first connection is disposed between the first vertically extending leg portion and the second vertically extending leg portion.

2. The semiconductor device of claim 1, wherein:
a plurality of second semiconductor chips are further disposed on the first upper metal layer along a second row parallel to the first row, and
the semiconductor device further comprising:
a second connection connecting the plurality of the second semiconductor chips in series and extending to a third upper metal layer, and
wherein, in the third upper metal layer, a third vertically extending leg portion and a fourth vertically extending leg portion of the first lead frame forming the fork shape together with the first vertically extending leg portion and the second vertically extending leg portion are disposed, and the second connection is disposed between the third vertically extending leg and the fourth vertically extending leg portion.

3. The semiconductor device of claim 2, wherein:
the first lead frame comprises a horizontally extending portion along a second direction perpendicular to the first direction, and
the first vertically extending leg portion, the second vertically extending leg portion, the third vertically extending leg portion, and the fourth vertically extending leg portion are formed to extend in the same direction from the horizontally extending portion.

4. The semiconductor device of claim 2, wherein:
the second upper metal layer and the third upper metal layer are formed to be spaced apart from each other.

5. The semiconductor device of claim 2, wherein:
a plurality of third semiconductor chips are further disposed on the first upper metal layer along a third row parallel to the first row, and
the semiconductor device further comprising,
a third connection connecting the plurality of third semiconductor chips in series and in parallel to each other; and
a second lead frame disposed below the third connection on one side of the first lead frame and providing power to the semiconductor device.

6. The semiconductor device of claim 5, wherein:
a plurality of fourth semiconductor chips are further disposed on the first upper metal layer along a fourth row parallel to the first row, and
the semiconductor device further comprising:
a fourth connection connecting the plurality of fourth semiconductor chips in series and in parallel to each other; and
a third lead frame disposed below the fourth connection on the other side of the first lead frame and providing power to the semiconductor device.

7. The semiconductor device of claim 2, wherein:
the first upper metal layer, the second upper metal layer, and the third upper metal layer are included in an upper substrate,
a ceramic layer is formed under the upper substrate, and
a lower metal layer is formed under the ceramic layer.

8. The semiconductor device of claim 6, wherein:
the first connection, the second connection, the third connection, and the fourth connection include a clip or a wire.
